(19) United States
(12) Patent Application Publication
(10) Pub. No.: US 2010/0144156 A1
(43) Pub. Date: Jun. 10, 2010

(54) METHOD TO INTEGRATE MICRO ELECTRO MECHANICAL SYSTEM AND CMOS IMAGE SENSOR

(76) Inventor: Hui-Shen Shih, Chang-Hua Hsien (TW)

Correspondence Address: NORTH AMERICA INTELLECTUAL PROPERTY CORPORATION, P.O. BOX 506, MERRIFIELD, VA, 22116, US

(21) Appl. No.: 12/331,422

(22) Filed: Dec. 9, 2008

(51) Int. Cl. H01L 21/306

(52) U.S. Cl. 438/704; 257/E21.219; 257/E21.215

(57) ABSTRACT

A method to integrate a micro electro mechanical system and a CMOS image sensor is disclosed. First a substrate is provided. The substrate includes a micro electro mechanical system (MEMS) region and a CMOS image sensor (CIS) region. The micro electro mechanical system region includes a micro electro mechanical system component and the CMOS image sensor region includes a CMOS image sensor element. Second, an etching procedure is performed on the substrate to form a micro electro mechanical system trench and a CMOS image sensor trench. The etching procedure includes at least a dry etching and at least a wet etching.

### BACKGROUND OF THE INVENTION

1. Field of the Invention

The present invention relates to a method to integrate a micro electro mechanical system and a CMOS image sensor. In particular, the present invention relates to a method to integrate a micro electro mechanical system and a CMOS image sensor by conventional semiconductor processes.

2. Description of the Prior Art

A micro electro mechanical system (MEMS) is a tiny device with both the electronic and mechanical functions. Apart from the conventional electro and mechanical processing, the micro electro mechanical system installs some micro structures, such as a circuit, a sensor, an actuator, a cantilever, a beam, a membrane, a channel, a cavity, a joint, a hinge, a link, a crank, a gear or a rack on a Si wafer by miniaturization techniques and is operated based on, for example, electromagnetic, electrostrictive, thermoelectric, piezoelectric, or piezoresistive effects. The manufacture method of the micro electro mechanical system therefore requires various processing techniques.

The current methods to manufacture the micro electro mechanical system are, for example, silicon-based method, the LIGA method and the polymer method. Considering the cost for the mass production, the well-developed semiconductor process is much favored to manufacture the micro electro mechanical system due to its potential capability.

As the development of electronic products such as digital cameras and mobile phones progresses, the demand for related components has increased as well. For example, as the development of digital cameras and scanners progresses, the demand for image sensor increases accordingly. In general, today's image sensors in common usage are divided into two main categories: the charge coupled device (CCD) sensors and the CMO image sensors (CIS). The application of CMOS image sensors has increased significantly for several reasons. Primarily, CMOS image sensors have certain advantages of offering low operating voltage, low power consumption, and the ability for random access. Additionally, CMOS image sensors are currently capable of integration with the semiconductor fabrication process.

The CMOS image sensor separates (i.e., classifies) incident light into a combination of light of different wavelengths. The light of different wavelengths is received by respective sensing elements, i.e. optically sensitive elements and is subsequently transferred into digital signals of different intensities. For example, the CMOS image sensor can consider incident light as a combination of red, blue, and green light. Those wavelengths are subsequently received by photodiodes, and then transformed into digital signals. However, in order to separate incident light, a monochromatic color filter array (CFA) must be set above every optical sensor element.

Because both the micro electro mechanical system and the CMOS image sensor element may be manufactured by the techniques which are integrated with the current semiconductor technology, the manufacturing process which integrates the micro electro mechanical system and the image sensor becomes a hot issue. In order to accommodate the components of the micro electro mechanical system, a trench is specially constructed in the substrate, for example by a wet etching step, to remove part of the substrate to accommodate the components of the micro electro mechanical system.

Similarly, for the complementary metal oxide semiconductor image sensor element, a trench is also specially constructed in the substrate, for example by a dry etching step, to remove part of the substrate to accommodate related elements, such as the aforesaid monochromatic color filter array or micro lenses, to eliminate the spaces to stack and to shorten the optical path. Although special trenches are needed in advance in the substrate for the micro electro mechanical system and the CMOS image sensor element, the techniques, i.e. the above-mentioned separately carried out dry etching and wet etching, to construct the trenches are distinctively different due to different properties of the micro electro mechanical system and of the CMOS image sensor element, which complicates the integration of the semiconductor process, raises the cost for manufacture and renders the products to be much less favorable.

Therefore, a novel method to integrate the micro electro mechanical system and the CMOS image sensor is needed to integrate the methods to construct the trenches, which simplifies the integration of the semiconductor process, lowers the cost for manufacture and renders the products to be much favorable.

### SUMMARY OF THE INVENTION

Accordingly, the present invention proposes a novel method to integrate the micro electro mechanical system and the CMOS image sensor element. What makes the method of the present invention outstanding is that it proposes a solution to integrate the method to construct the trenches for both the micro electro mechanical system and the CMOS image sensor element, that is, to synchronously construct the trenches for both the micro electro mechanical system and the CMOS image sensor element. The method of the present invention may simplify the integration of the semiconductor process, lower the cost for manufacture and render the products to be much favorable.

The present invention proposes a method to integrate a micro electro mechanical system and a CMOS image sensor. First, a substrate is provided. The substrate includes a micro electro mechanical system (MEMS) region and a CMOS image sensor (CIS) region. The micro electro mechanical system region includes a micro electro mechanical system component and the CMOS image sensor region includes a CMOS image sensor element. Second, an etching procedure is performed on the substrate to form a micro electro mechanical system trench in the micro electro mechanical system region and a CMOS image sensor trench in the CMOS image sensor region. The etching procedure includes at least a dry etching and at least a wet etching. Preferably, a dry etching is first performed in the etching procedure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate a preferred example of the method to integrate a micro electro mechanical system and a CMOS image sensor.

FIG. 4 illustrates the monochromatic color filter array and micro lenses in the CMOS image sensor trench.

### DETAILED DESCRIPTION

The present invention provides a novel method to integrate the micro electro mechanical system and the CMOS image sensor element. Through a single etching procedure the trenches may be synchronously constructed for both the micro electro mechanical system and the CMOS image sensor element. The method of the present invention may simplify the integration of the semiconductor process, lower the cost for manufacture and render the products to be much favorable.

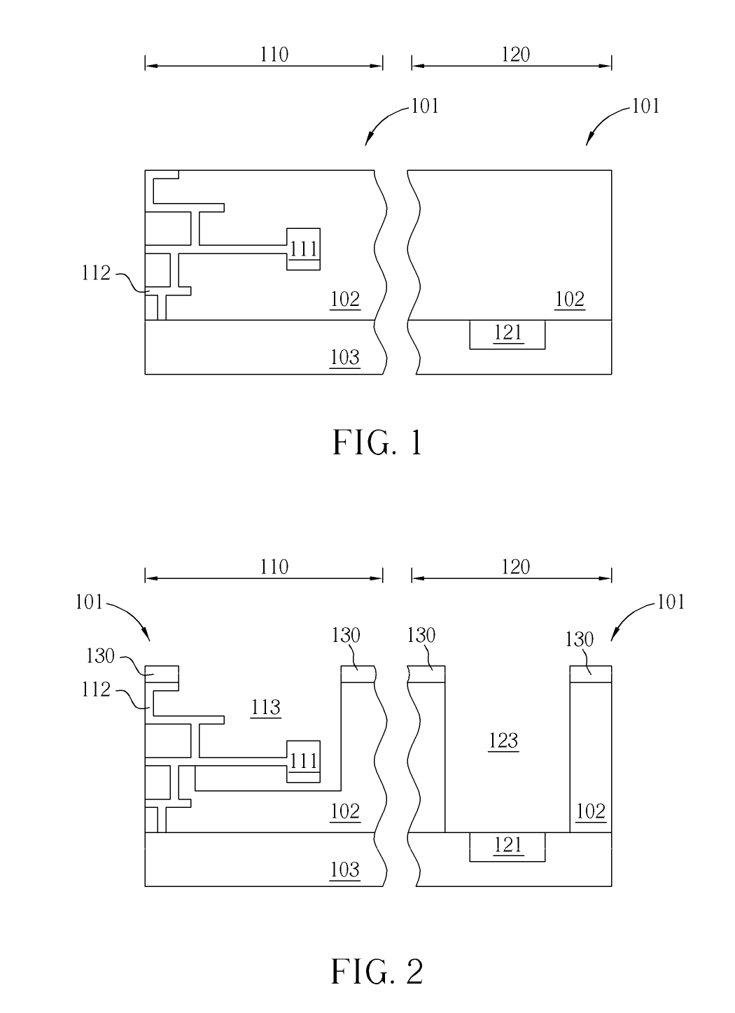

Please refer to FIGS. 1-3, which illustrate a preferred example of the method to integrate a micro electro mechanical system and a CMOS image sensor. As shown in FIG. 1, first a substrate 101 is provided. The substrate 101 includes a micro electro mechanical system (MEMS) region 110 and a CMOS image sensor (CIS) region 120. A micro electro mechanical system or at least one micro electro mechanical system component 111 has been formed in the micro electro mechanical system region 110. As to the CMOS image sensor region 120, at least one CMOS image sensor element 121 has been formed therein. The substrate 101 may further include a protective structure 140 surrounding the micro electro mechanical system (MEMS) region 110.

The substrate 101 may include various layers. As shown in FIG. 1, for example, the substrate 101 may have a dielectric layer 102 and a Si layer 103. The dielectric layer 102 may include oxide or nitride. Preferably, the component 101 is disposed in the dielectric layer 102. In addition, the substrate 101 may include other regions, for example a logic region (not shown) and a seal ring region (not shown). The logic region is used to form the required logic elements, for example a metal-oxide semiconductor. The seal ring region surrounds the micro electro mechanical system region 110 to form a pre-determined seal ring (not shown), or as a protective structure in order to protect the pre-determined micro electro mechanical system. The substrate 101 may further include doped regions or other material layers in advance, such as a contact etch stop layer (CESL) (not shown) or an inter layer dielectric layer (not shown).

Because different micro electro mechanical systems need different micro electro mechanical system components 111, such as a microphone or a joystick, the micro electro mechanical system components 111 are optionally different. For example, if the micro electro mechanical system is a microphone, the micro electro mechanical system component 111 may be a diaphragm. Or, if the micro electro mechanical system is a joystick, the micro electro mechanical system component 111 may be a motion sensor. Besides, in the micro electro mechanical system region 110 there may be multiple metal interconnections 112. The methods to form the micro electro mechanical system component 111, the CMOS image sensor element 121 and the multiple metal interconnections 112 are well known to persons of ordinary skills in the art and the details will not be described here.

Second, please refer to FIG. 2, an etching procedure is performed on the substrate 101. The etching procedure constructs a micro electro mechanical system trench 113 in the micro electro mechanical system region 110 and a CMOS image sensor trench 123 in the CMOS image sensor region 120. The dimension and the depth of the micro electro mechanical system trench 113 and the CMOS image sensor trench 123 depend on the size and the process control of the micro electro mechanical system component 111, the CMOS image sensor element 121 and the multiple metal interconnections 112. Preferably, the micro electro mechanical system trench 113 exposes the micro electro mechanical system component 111 completely.

The etching procedure includes performing at least a dry etching step and at least a wet etching step, and preferably, the dry etching step and the wet etching step are carried out in alternative order. The dry etching step may rapidly construct the contour of the micro electro mechanical system trench 113 as well as the CMOS image sensor trench 123. Preferably, the dry etching step exposes the micro electro mechanical system component 111. The wet etching step may break through the block or hindrance of the micro electro mechanical system component 111 and modify the desirable shape of the trenches. Preferably, the dry etching step is first carried out in the etching procedure and uses the above-mentioned material layer, such as the CESL or ILD as an etching stop layer. For example, if the dry etching step is first carried out in the etching procedure, the dry etching step would primarily construct 80% of the volume or contour of the trenches.

The method to perform the etching procedure may be as follows. First, a photo resist 130 is used to define the micro electro mechanical system trench 113 and the CMOS image sensor trench 123. Later, the first dry etching step is carried out to roughly construct the approximate volume of the trenches. The first wet etching step proceeds with the insufficient part, such as the region under the micro electro mechanical system component 111. Optionally, a second dry etching step and/or a second wet etching step . . . etc. may proceed to finish the micro electro mechanical system trench 113 and the CMOS image sensor trench 123. In one preferred embodiment of the present invention, the dry etching step is first carried out to roughly construct 80%-90% deep of the trenches, and the wet etching step proceeds to remove the blocked region (remaining 20%-10% depth) under the micro electro mechanical system component 111, to do the work which the dry etching step fails to do or is barely able to do. The method of the present invention enjoys the advantages of both the dry etching step and the wet etching step and at the same time avoids the disadvantages of the dry etching step and the wet etching step which are separately used.

Different etchants may be separately used to carry out the dry etching step and the wet etching step. For example, fluoro-containing plasma may be used to perform the dry etching step. Or, fluorides may be used to perform the wet etching step. The fluorides may be liquid or gas. For example, the gaseous fluoride is vapor HF, (VHF). The liquid fluoride is dilute HF, (DHF).

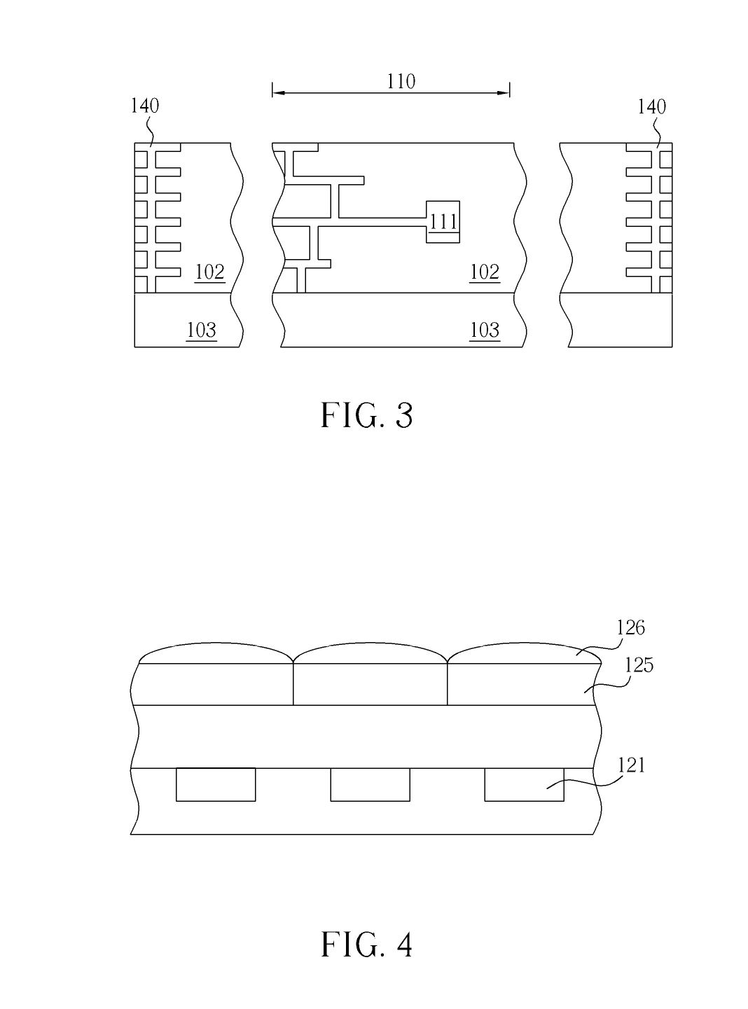

After the micro electro mechanical system trench 113 and the CMOS image sensor trench 123 are completed, the following steps may proceed. FIG. 4 illustrates the monochromatic color filter array and micro lenses in the CMOS image sensor trench. As shown in FIG. 4, in the readily formed CMOS image sensor trench 123, the monochromatic color filter array 125 and micro lenses 126 . . . etc. are formed to correspond to the underlying the CMOS image sensors 121. The methods to form the monochromatic color filter array 125 and micro lenses 126 are well known to persons of ordinary skills in the art and the details will not be described here.

Those skilled in the art will readily observe that numerous modifications and alterations of the device and method may be made while retaining the teachings of the invention.

What is claimed is:

1. A method to integrate a micro electro mechanical system and an image sensor, comprising:
providing a substrate comprising a micro electro mechanical system (MEMS) region and an image sensor region, said micro electro mechanical system region comprising a micro electro mechanical system component and said image sensor region comprising an image sensor element; and
performing an etching procedure on said substrate to form a micro electro mechanical system trench in said micro electro mechanical system region and an image sensor trench in said image sensor region, said etching procedure comprising carrying out at least a dry etching and at least a wet etching.

2. The method to integrate a micro electro mechanical system and an image sensor of claim 1, wherein said substrate comprises a protective structure surrounding said micro electro mechanical system region.

3. The method to integrate a micro electro mechanical system and an image sensor of claim 1, further comprising:
forming a micro electro mechanical system in said micro electro mechanical system region and an image sensor in said image sensor region.

4. The method to integrate a micro electro mechanical system and an image sensor of claim 1, wherein said micro electro mechanical system component comprises a diaphragm.

5. The method to integrate a micro electro mechanical system and an image sensor of claim 1, wherein said micro electro mechanical system component comprises a motion sensor.

6. The method to integrate a micro electro mechanical system and an image sensor of claim 1, wherein said image sensor comprises a CMOS Image Sensor (CIS).

7. The method to integrate a micro electro mechanical system and an image sensor of claim 1, wherein said dry etching is first carried out in said etching procedure.

8. The method to integrate a micro electro mechanical system and an image sensor of claim 7, wherein said dry etching exposes said micro electro mechanical system component in said micro electro mechanical system region.

9. The method to integrate a micro electro mechanical system and an image sensor of claim 1, wherein a fluoride is used as an etchant in said wet etching.

10. The method to integrate a micro electro mechanical system and an image sensor of claim 9, wherein said etchant is a liquid fluoride.

11. The method to integrate a micro electro mechanical system and an image sensor of claim 9, wherein said etchant is a gaseous fluoride.

12. The method to integrate a micro electro mechanical system and an image sensor of claim 1, wherein said dry etching step is carried out to construct 80%-90% of a total depth.

13. The method to integrate a micro electro mechanical system and an image sensor of claim 12, wherein said wet etching step proceeds to finish the remaining depth 20%-10%.
